(19) United States
(12) Patent Application Publication
(10) Pub. No.: US 2024/0130236 A1
(43) Pub. Date: Apr. 18, 2024

(54) METHOD FOR MANUFACTURING A THERMOELECTRIC STRUCTURE

(71) Applicant: COMMISSARIAT À L'ÉNERGIE ATOMIQUE ET AUX ÉNERGIES ALTERNATIVES, Paris (FR)

(72) Inventors: Guillaume Savelli, Grenoble (FR); Maxime Baudry, Grenoble (FR); Guilhem Roux, Grenoble (FR)

(21) Appl. No.: 18/485,424

(22) Filed: Oct. 12, 2023

(30) Foreign Application Priority Data
Oct. 14, 2022 (FR) 2210613

(51) Int. Cl. H10N 10/01

(52) U.S. Cl. CPC H10N 10/01

(57) ABSTRACT

A method for manufacturing a thermoelectric structure including the following steps: a) providing a substrate made from a first material, b) depositing a thermoelectric element made from a second material on the substrate, by additive manufacturing, preferably by SLS or PBF, c) thinning and cutting the substrate until a film made from the first material is obtained, by means of which a thermoelectric structure comprising a film and the thermoelectric element is obtained.

### CROSS-REFERENCE TO RELATED APPLICATIONS

This application claims priority from French Patent Application No. 2210613 filed on Oct. 14, 2022. The content of this application is incorporated herein by reference in its entirety.

### TECHNICAL FIELD

The present invention relates to the general field of thermoelectric modules.

The invention relates to a method for manufacturing thermoelectric structures.

The invention also relates to a thermoelectric structure obtained by such a method.

The invention also relates to thermoelectric devices comprising two thermoelectric structures thus obtained, one being with a first conductivity type and the other being with a second conductivity type.

The invention finds applications in numerous industrial fields, and in particular for applications needing thermoelectric generators, where a thermal gradient is available (e.g. transport, industry, etc.), radioisotope thermoelectric generator applications, Peltier applications or thermal sensor applications.

The invention is particularly interesting since it makes it possible to form thermoelectric structures/devices having low resistivities.

### PRIOR ART

Generally, thermoelectric (TE) modules comprise a set of first pins made from a thermoelectric material with a first conductivity type and a set of second pins made from a piezoelectric material with a second conductivity type. For example, the first material is an N-type material (i.e. with N-type conductivity) and the second material is a P-type material (i.e. with P-type conductivity).

The pins are connected electrically in series and thermally in parallel. The pins are connected together by metal elements. The thermoelectric junctions are also referred to as NP junctions. The pins are held by ceramic substrates disposed on either side of the pin assemblies.

The electrical performances of a TE device in generator mode are given by: an internal electrical resistance Rₐₙₜ defined according to (1):

Rᵢₙₜ=N×ρₙₚ×L/A+R_{c}+Rₘₑₜ (1)

with N the number of NP junctions, ρₙₚ the electrical resistivity of the NP materials, L the length of a line or thickness of a pin, A the cross section of a line or of a pin, R_{c} the total resistance of the contacts and Rₘₑₜ the total resistance of the metal junctions

a useful electric power Pu defined according to (2),

Pu=V_{oc}²/4Rᵢₙₜ

with V_{oc} the voltage generated by the TE module.

Thus, to have high power, it is necessary to have a low internal electrical resistance, and therefore to reduce the contribution of the total resistance of the contacts R_{c} and of the total resistance of the metal junctions Rₘₑₜ.

Conventionally, TE modules are generally manufactured using the following steps: manufacture of the TE materials (sintering), formation of the pins, metallisation of the pins, assembly with the substrates.

The metal connections are made directly on the substrates, for example by the so-called direct-copper technique (or DBC, standing for “Direct Bonding Copper”), and then brazing and pressing with the pins.

However, this manufacturing method is relatively complex and greatly limits the geometry and modularity of the manufactured thermoelectric device.

There are also TE modules without substrate, also referred to as “skeleton modules”. These modules therefore do not have any heat loss due to the substrates. However, they cannot be in contact with electrically conductive surfaces.

It is also possible to use TE pins produced from several TE materials. These so-called segmented pins make it possible to accommodate a greater temperature difference at the ends of the module since the materials used are generally optimised for different temperature ranges.

### DESCRIPTION OF THE INVENTION

One aim of the present invention is to propose a method for manufacturing thermoelectric structures that is simple to implement and makes it possible to manufacture thermoelectric structures having good electrical properties (in particular low contact resistance) and/or good thermal properties.

For this purpose, the present invention proposes a method for manufacturing a thermoelectric structure comprising the following steps:

providing a substrate made from a first material,

b) depositing a thermoelectric element made from a second material on the substrate, by additive manufacturing,

c) thinning and cutting the substrate, until a film made from the first material is obtained, by means of which a thermoelectric structure comprising a film made from the first material and the thermoelectric element is obtained.

The invention is fundamentally distinguished from the prior art by the implementation of a step during which the functionalisation (metallisation) of the thermoelectric element (for example a thermoelectric pin) is implemented during the additive manufacturing method.

This leads not only to an appreciable reduction in the number of steps and therefore to a simplification of the method compared with the methods of the prior art, but also to a considerable saving in time and to a reduction in costs.

The metallisation obtained has good mechanical strength and good electrical and/or thermal conduction properties.

Preferably, the additive manufacturing technique is a laser powder bed fusion (PBF for Powder Bed Fusion) technique or a selective laser sintering (SLS) technique.

Advantageously, the substrate is covered, completely or locally, with a metal bonding layer made from a third material and the thermoelectric element is formed on the metal bonding layer, by means of which a thermoelectric structure comprising a film, a bonding layer and a thermoelectric element is obtained, the third material preferably being selected from Al, Ti, Cu, Au and Ni.

According to an advantageous embodiment, the thermoelectric element is a part in the form of a comb delimiting a base and a plurality of arms, substantially parallel to each other, extending substantially orthogonally from the base, the plurality of arms having a first end and a second end, the first end being connected to the base, and the second end being in contact with the film or, where applicable, in contact with the metal bonding layer.

According to another advantageous embodiment, the thermoelectric element is a pin, having a base and a height.

According to this other advantageous embodiment, the substrate can be cut so as to have a film having the same surface area as the surface area of the base of the pin. Alternatively, the substrate can be cut so as to have a film having a surface area greater than the surface area of the base of the pin.

Advantageously, in step b), a plurality of pins are deposited and the substrate is cut so as to have a structure comprising a film on which a plurality of pins are disposed.

Advantageously, between step b) and step c), the method comprises an additional step during which an intermediate metallisation layer and then an additional thermoelectric element made from a fourth material having a conductivity type opposite to the conductivity type of the second material are deposited on the thermoelectric element. For example, the second material is N type and the fourth material is P type (or vice versa).

Advantageously, the second material is Si, SiGe, Bi₂Te₃, Half-Heusler or Skutterudites.

The fourth material can also be selected from Si, SiGe, Bi₂Te₃, Half-Heusler and Skutterudites. For example, the second material is N-doped SiGe and the fourth material is P-doped SiGe.

Advantageously, the first material is 316L steel, aluminium, titanium, a CuZr alloy, a ceramic or graphite.

The method has numerous advantages:

it has a small number of steps,

it is simple and economical,

it allows great modularity of design of the thermoelectric device manufactured, for example,

the thermoelectric elements can have simple forms (a pin for example) or complex forms (a comb for example).

The invention also relates to a thermoelectric structure obtained by such a method.

The thermoelectric structure comprises a film, for example made from 316L steel, aluminium, titanium, CuZr alloy, ceramic or graphite, on which one or more thermoelectric elements are disposed.

Advantageously, a metal bonding layer, for example made from Al, Ti, Cu, Au or Ni, is disposed between the film and the thermoelectric element or elements.

Additive manufacturing makes it possible to produce complex shapes, which is not possible with the current techniques for manufacturing TE materials. The complex shapes are for example circular shapes. It is also possible to produce thermoelectric elements having cavities or thermoelectric elements in honeycomb or spiral form. Square shapes, which are simpler to produce, are also achievable.

The invention also relates to a thermoelectric device comprising two thermoelectric structures obtained by a method as described previously, each thermoelectric structure comprising a film, for example made from 316L steel, aluminium, titanium, CuZr alloy, ceramic or graphite, and one or more thermoelectric elements, a metal bonding layer, for example made from Al, Ti, Cu, Au or Ni, able to be disposed between the film and the thermoelectric element or elements of the two thermoelectric structures, the thermoelectric element or elements of one of the thermoelectric structures being of a first conductivity type and the thermoelectric element or elements of the other thermoelectric structure being of a second conductivity type opposite to the first conductivity type.

Other features and advantages of the invention will become apparent from the following additional description.

It goes without saying that this additional description is given only as an illustration of the object of the invention and should in no way be interpreted as a limitation of this object.

### BRIEF DESCRIPTION OF THE DRAWINGS

The present invention will be better understood upon reading the description of embodiments given merely for indication and without limitation with reference to the appended drawings wherein:

FIG. 1A, FIG. 1B and FIG. 1C show, schematically and in cross-section, the various steps of a method for manufacturing a thermoelectric structure according to a first embodiment of the invention.

FIG. 2A, FIG. 2B, FIG. 2C and FIG. 2D show, schematically and in cross-section, the various steps of a method for manufacturing a thermoelectric structure according to a second embodiment of the invention.

FIG. 3A, FIG. 3B, FIG. 3C, FIG. 3D and FIG. 3E show, schematically and in cross-section, the various steps of a method for manufacturing a thermoelectric structure according to a third embodiment of the invention.

FIG. 4A, FIG. 4B, FIG. 4C, FIG. 4D, FIG. 4E and FIG. 4F show, schematically and in cross-section, the various steps of a method for manufacturing a thermoelectric structure according to a fourth embodiment of the invention.

FIG. 5A, FIG. 5B and FIG. 5C show, schematically and in cross-section, the various steps of a method for manufacturing a thermoelectric structure according to a fifth embodiment of the invention.

FIG. 6A, FIG. 6B, FIG. 6C and FIG. 6D show, schematically and in cross-section, the various steps of a method for manufacturing a thermoelectric structure according to a sixth embodiment of the invention.

FIG. 7 is a photograph of thermoelectric pins deposited on a substrate according to a particular embodiment of the invention.

The various parts shown in the figures are not necessarily plotted according to a uniform scale, to make the figures more readable.

The various possibilities (alternatives and embodiments) must be understood as not being mutually exclusive and can be combined with one another.

Moreover, in the description below, the terms that depend on the orientation, such as “above”, “below”, etc. of a structure apply for a structure that is considered to be oriented in the manner illustrated in the figures.

### Detailed Description of Specific Embodiments

Although this is in no way limitative, the invention is particularly interesting for applications needing thermoelectric generators (TEG, standing for “ThermoElectric Generator”), where a thermal gradient is available (e.g. transport, industry, etc.), radioisotope thermoelectric generator applications (RTG, standing for “Radioisotope Thermoelectric Generators”) in particular for SiGe, Peltier applications or thermal sensor applications.

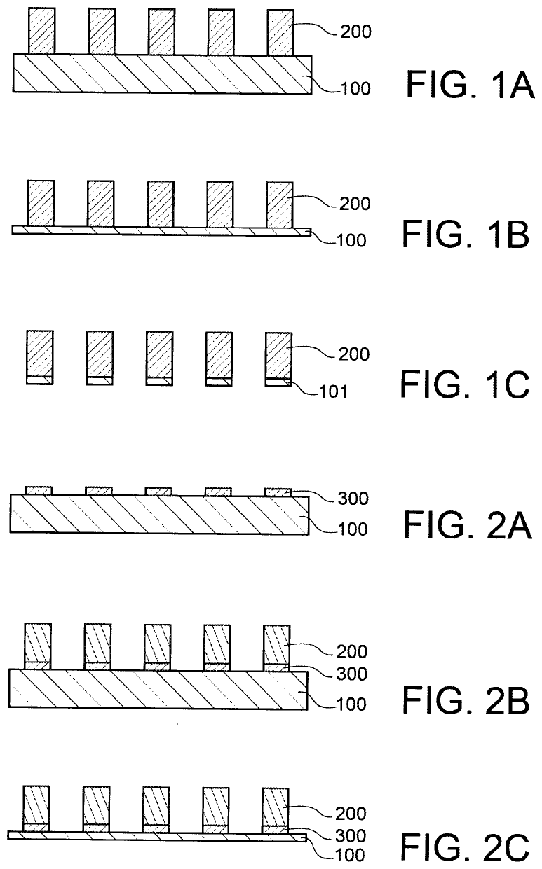

As shown in FIG. 1A to 1C, 2A to 2D, 3A to 3E, 4A to 4F, 5A to 5C, 6A to 6D, the method for manufacturing a thermoelectric structure comprises the following steps: providing a substrate 100 made from a first material,

b) depositing a thermoelectric element 200 made from a second material on the substrate 100, by additive manufacturing, preferably selective laser sintering (SLS) or by laser powder bed fusion (PBF),

c) thinning and cutting the substrate 100 until a film 101 made from the first material is obtained, by means of which a thermoelectric structure comprising a film 101 made from the first material and the thermoelectric element 200 is obtained.

The substrate 100 provided at step a) may be a plate or an overplate.

In additive manufacturing machines, the overplates are attached directly to the plates, and make it possible not only to obtain finer thicknesses (between 200 μm and a few millimetres), but also to increase the nature of the materials that can be used. The overplate is advantageously made from ceramic.

The substrate 100 is for example made from a metal (for example Al, Ti, Cu, Au or Ni), from a metal alloy, from a semiconductor material, from ceramic or from graphite. For example, it is made from 316L steel, aluminium, titanium, CuZr, ceramic or graphite.

The substrate 100 can have a thickness ranging from a few hundreds of micrometres to a few centimetres, or preferably from a few hundreds of micrometres to a few millimetres.

The thermoelectric element 200 deposited at step b) is made from a second material. The second material is preferably selected from Si, SiGe, MnSi, Bi₂Te₃, Half-Heusler and Skutterudites. Skutterudites are mineral species composed of cobalt and nickel arsenide of formula (Co, Ni)As₃₋ₓ with traces of S, Bi, Cu, Pb, Zn, Ag, Fe and Ni.

The thermoelectric element 200 can have N-type conductivity to favour the movement of the electrons (i.e. the material that makes it up has a strictly negative Seebeck coefficient) or P-type conductivity to favour the movement of the holes (i.e. the material that makes it up has a strictly positive Seebeck coefficient).

For example, the N-type doped thermoelectric material is a silicon-germanium (SiGe) alloy doped by phosphorus or N-type doped polysilicon. The N-type dopant can be phosphorus or arsenic.

For example, the P-type doped material is a silicon-germanium (SiGe) alloy doped by boron or P-type doped polysilicon. The P-type dopant is preferentially boron.

Advantageously, the dopant is directly integrated in the base powder.

The thermoelectric element 200 can be formed directly on the substrate 100. It is then in direct contact with the substrate 100.

According to an advantageous variant embodiment, the substrate 100 provided at step a) can be covered with a bonding layer 300 made from a third material. During step b), the thermoelectric element 200 is then formed on the metal bonding layer 300. It is directly in contact with this bonding layer 300. In this way a thermoelectric structure is obtained comprising a film 101, a bonding layer 300 and a thermoelectric element 200.

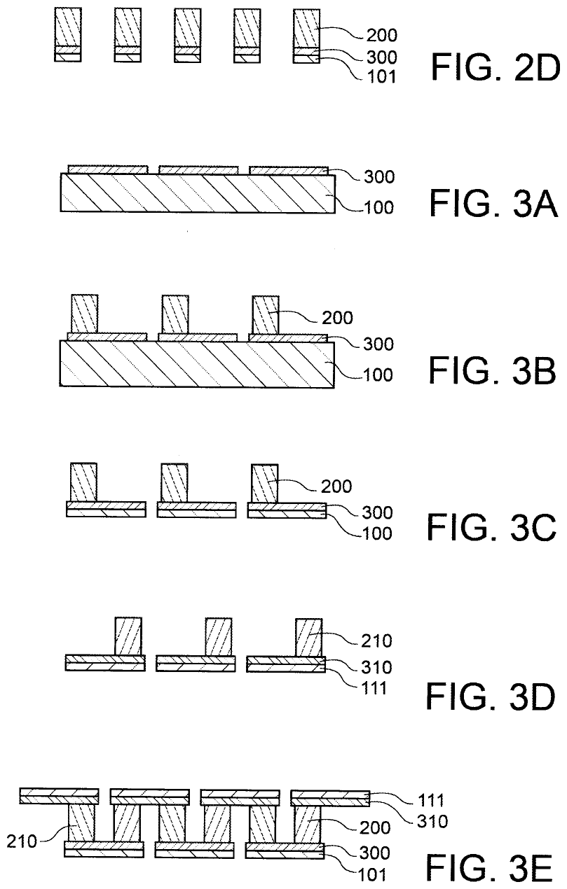

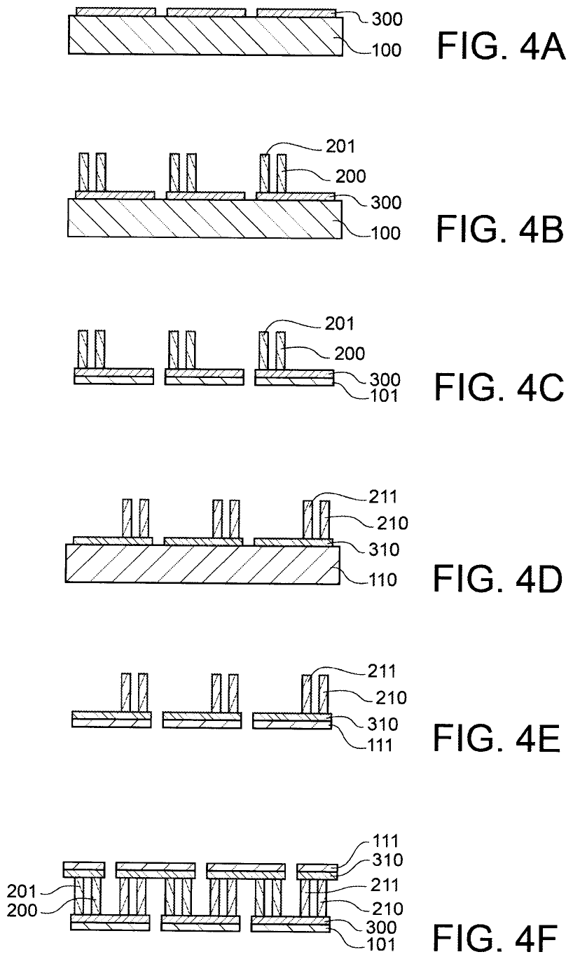

The bonding layer 300 can cover the substrate 100 locally or completely. For example, the metal bonding layer 300 forms a plurality of islands on the surface of the substrate 100. A thermoelectric element 200 can be formed on each island (FIG. 2B, 3B, 6A) or a plurality of thermoelectric elements 200, 201 can be formed on each island (FIG. 4B).

To obtain a bonding layer 300 covering the substrate 100 locally, it is possible to implement a localised deposition of this layer. Alternatively, it is possible to implement a full deposition of a continuous layer followed by a step during which part of the continuous layer is removed, for example by etching, to form the islands.

The bonding layer 300 may be deposited, for example, by physical vapour deposition (PVD), by evaporation or by sputtering.

After the deposition of the bonding layer 300, an annealing step may be implemented.

The bonding layer 300 is made from a material different from that of the substrate 100.

The bonding layer 300 is, for example, made from metal or from a metal alloy. Preferably, the metal is selected from Al, Ti, Cu, Au and Ni. Several layers can be superimposed, for example, it may be a dual layer or a triple layer. A triple layer formed from a layer of copper, from a layer of nickel and from a layer of gold can be selected. By way of illustration and non-limitatively, it is possible to select a triple layer formed from Cu (for example 200 nm)+Ni (for example 5 μm)+Au (for example 10 nm).

The thermoelectric element 200 deposited at step b) is obtained by additive manufacturing. The method consists in depositing the material in several successive passes on the substrate or on the bonding layer. At the end of successive depositions, the thermoelectric element is obtained. The substrate may be a plate or an overplate.

Preferably, the additive manufacturing technique is a powder bed laser fusion (PBF) technique or a selective laser sintering (SLS) technique.

The PBF methods consist in melting certain regions of a powder bed, for example by means of a laser beam.

In the SLS method, the powders are sintered. The materials of the powders do not go into a liquid phase.

However, other additive manufacturing techniques can be envisaged, such as cold spray, electron beam melting, etc.

The thermoelectric element 200 deposited at step b) can take several forms.

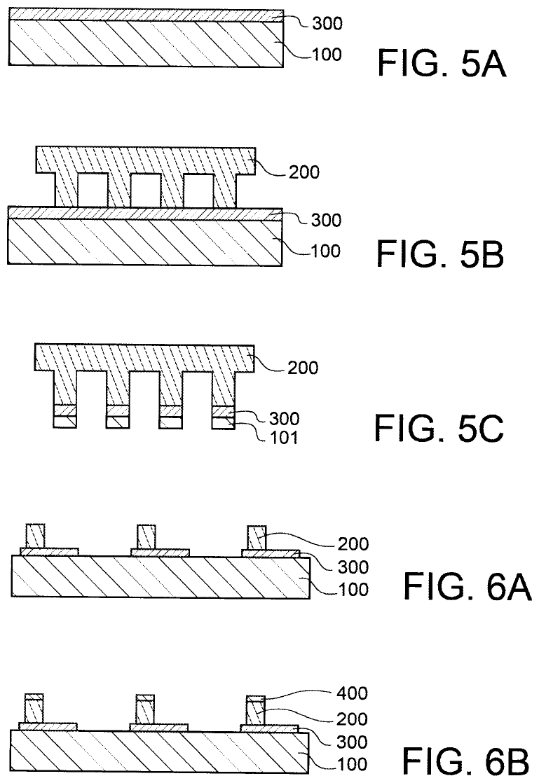

According to a first advantageous variant embodiment, the thermoelectric element 200 is a part in the form of a comb (FIG. 5B).

The part is in the form of a comb delimiting a base and a plurality of arms, substantially parallel to each other, extending substantially orthogonally from the base. The plurality of arms have a first end and a second end. The first end is connected to the base, and the second end is in contact with the film 101 or, where applicable, in contact with the metal bonding layer 300.

“Substantially orthogonal” means “orthogonal” or “orthogonal to within plus or minus 10° of tolerance”.

“Substantially parallel” means “parallel” or “parallel to within plus or minus 10° of tolerance”.

According to another variant embodiment, the thermoelectric element 200 is a pin (FIG. 1B, 2B, 3B, 4B, 6A). The pin has a base having a surface and a height.

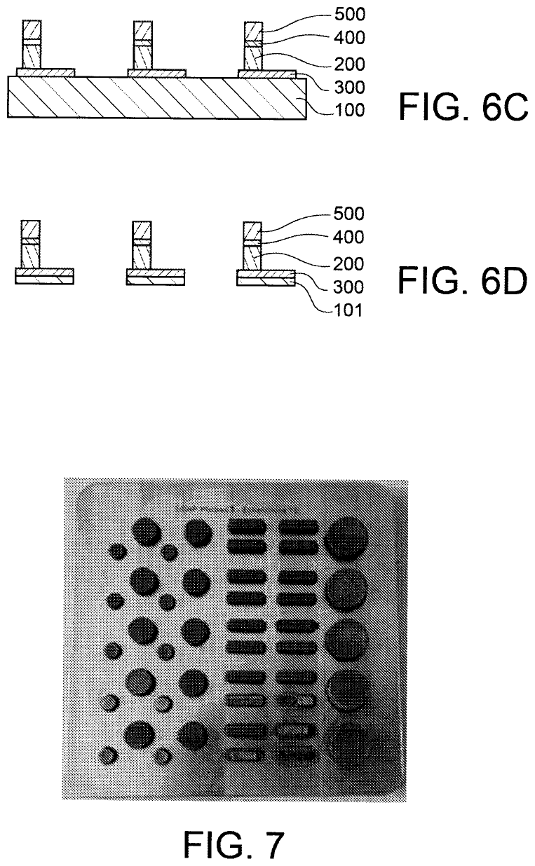

According to a particular embodiment, between step b) and step c), the method comprises an additional step during which an intermediate metallisation layer 400 (FIG. 6B) and then an additional thermoelectric element 500 made from a fourth material (FIG. 6C) are deposited on the thermoelectric element 200. The fourth material is different from the second material.

After step b), a thermal annealing can be implemented.

During step c), the substrate 100 is thinned and cut to form a film 200 facing the thermoelectric element 200.

The substrate 100 can be thinned by laser, mechanical machining, water jet, electroerosion or by electrochemical machining.

The substrate 100 can be cut by laser, wire saw, etc.

According to a first variant embodiment, in step c), the substrate 100 is cut so as to have a film 101 having the same surface area as the surface area of the base of the pin or of the second end of the arms of the comb.

According to another variant embodiment, in step c), the substrate 100 is cut so as to have a film 101 having a surface area greater than the surface area of the base of the pin.

Highly advantageously, in step b), a plurality of pins 200, 201 are deposited (FIG. 4B, 4D) and the substrate 100 is cut so as to have a structure comprising a film 101 on which a plurality of pins 200, 201 (FIG. 4C, 4E) are disposed.

At the end of step c), a first thermoelectric structure is thus obtained.

Advantageously, the previously described manufacturing method is used to manufacture a second thermoelectric structure (as for example shown on FIGS. 3D and 4E).

The second structure comprises a film 111 obtained after thinning and cutting of the substrate 100 and one or more thermoelectric elements 210, 211. A bonding layer 310 can be disposed between the film 111 and the thermoelectric element or elements 210, 211.

The thermoelectric material of the second structure has a doping different from that of the first structure.

The two structures obtained are advantageously assembled and electrically connected to form a thermoelectric device (FIGS. 3E and 4F).

It is possible to connect the devices in series and/or in parallel. It is advantageous to combine series connections and parallel connections in order to optimise the output electrical performances of the thermoelectric device manufactured.

Where applicable, the materials of the metal layers 300, 310 of the two structures may be identical or different. The materials of the substrates 100, 110 used may be different identical or different.

The invention is particularly advantageous for manufacturing conventional

thermoelectric modules, DBC substrates, so-called skeleton thermoelectric modules or segmented thermoelectric pins.

The thermoelectric device obtained can operate in Seebeck mode (i.e. the thermoelectric device is then an electrical energy generator) or in Peltier mode (i.e. the thermoelectric device is then a thermal energy generator).

Various embodiments will now be described in more detail with reference to the accompanying figures.

According to a first embodiment shown in FIG. 1A to 1C, the method comprises the following steps:

providing a substrate 100 made from a first material,

b) depositing a thermoelectric pin 200, and preferably a plurality of thermoelectric pins, made from a second material on the substrate 100, by additive manufacturing, preferably by SLS or PBF,

c) thinning and cutting the substrate 100, by means of which one or more thermoelectric structures each comprising a thermoelectric pin 200 covered by a film 101 made from the first material are obtained.

This first embodiment is advantageous since it makes it possible to directly use the material of the substrate 100 (preferably made from metal or from metal alloy) for metallising the pins 200.

According to a second embodiment shown in FIG. 2A to 2D, the method comprises the following steps:

providing a substrate 100 made from a first material, locally covered with a metal bonding layer 300 made from a third material, forming islands,

b) depositing a thermoelectric pin 200, and preferably a plurality of thermoelectric pins, made from a second material on each island of the bonding layer 300, by additive manufacturing, preferably by SLS or PBF,

c) thinning and cutting the substrate 100, by means of which a plurality of thermoelectric structures, each comprising a thermoelectric pin 200 covered successively by a bonding layer 300 and a film 101 made from the first material, are obtained.

This second embodiment is advantageous since it makes it possible to directly use the material of the substrate 100 (plate) for metallising the pins 200, the mechanical strength of the metallisation being improved by the presence of the bonding layer 300. In these first embodiments, the substrate 100 is cut to the size of the pins 200.

According to a variant embodiment, the substrate 100 can be cut so as to have a surface area greater than the surface area of the base of the pins 200.

For example, according to a third embodiment shown in FIG. 3A to 3C, the method comprises the following steps:

providing a substrate 100 made from a first material, locally covered with a metal bonding layer 300 made from a third material, forming islands,

b) depositing a thermoelectric pin 200 made from a second material on the substrate 100, by additive manufacturing, preferably by SLS or PBF, on each island,

c) thinning and cutting the substrate 100, by means of which a plurality of structures, each comprising a film 101 made from the first material covered by a bonding layer 300 and then by a thermoelectric pin 200, are obtained.

Advantageously, the same method is used for manufacturing other thermoelectric structures, each comprising a film 111 made from the first material covered by a bonding layer 310 and then by a thermoelectric pin made from a fourth material with conductivity opposite to the conductivity of the second material (FIG. 3D). The two devices are next assembled to form, preferably, skeleton modules (FIG. 3E).

For example, according to a fourth embodiment shown in FIG. 4A to 4C, the method comprises the following steps:

providing a substrate 100 made from a first material, locally covered with a metal bonding layer 300 made from a third material, forming islands,

b) depositing a plurality of thermoelectric pins 200, 201, made from a second material on each island of the metal bonding layer 300, by additive manufacturing, preferably by SLS or PBF,

c) thinning and cutting the substrate 100, by means of which a structure is obtained comprising a film 101 made from the first material covered by a bonding layer 300 on which a plurality of thermoelectric pins 200, 201 are disposed.

Advantageously, the same method is used for manufacturing an additional structure from a substrate 110, locally covered by a metal bonding layer 310 on which a plurality of pins 210, 211 are formed by additive manufacturing (FIG. 4D to 4F).

This additional structure comprises a film 111 covered by a bonding layer 310 on which are disposed a plurality of thermoelectric pins 210, 211 with conductivity opposite to the conductivity of the pins 200, 201 of the first structure (FIG. 4E). The two devices are next assembled to form, preferably, skeleton modules (FIG. 4F).

This fourth embodiment is particularly advantageous since it makes it possible to combine series/parallel connections and thus to optimise the output electrical performances. This is because it is possible to electrically connect the various thermoelectric pins as needed. Usually, all the pins are electrically connected in series. But this may lead to obtaining high output voltages (of several volts), which is incompatible with associated electronics (“power management unit”), for which the voltages are generally of a few volts. This embodiment makes it possible to connect some pins in parallel while decreasing the output voltage, and while maintaining the generated power.

According to a fifth embodiment shown in FIG. 5A to 5C, the method comprises the following steps:

providing a substrate 100 made from a first material, covered with a metal bonding layer 300 made from a third material,

b) forming a thermoelectric part 200 in the form of a comb, made from a second material on the metal bonding layer 300, by additive manufacturing, preferably by SLS or PBF, the part being a comb,

c) thinning and cutting the substrate 100, and cutting the bonding layer 300, by means of which a comb 200, the second end of the arms of which is covered by a bonding layer 300 and by a film 101 made from the first material, is obtained.

The same method is used for manufacturing a comb with a conductivity type opposite to the conductivity type of the second material. The two combs are next assembled.

According to a sixth embodiment shown in FIG. 6A to 6D, the method comprises the following steps: providing a substrate 100 made from a first material, locally covered with a metal bonding layer 300, forming islands,

b) depositing a thermoelectric pin 200 made from a second material on each island of the bonding layer 300, by additive manufacturing, preferably by SLS or PBF, and then a metallisation layer 400 and another thermoelectric element 500 made from a fourth material,

c) thinning and cutting the substrate 100, until a film 101 made from the first material is obtained, by means of which thermoelectric structures are obtained, each comprising a film 101, a bonding layer 300, a first thermoelectric pin 200, a metallisation layer 400 and then a second thermoelectric pin 500.

This embodiment is particularly advantageous for manufacturing segmented thermoelectric pins.

### Illustrative and Non-Limiting Examples of One Embodiment

In this example, thermoelectric elements made from SiGe, in pin form, were manufactured by SLS. The thermoelectric elements can have a thickness of 500 μm to a few centimetres.

The plate is made from 316L stainless steel.

FIG. 7 shows thermoelectric elements thus manufactured.

1. A method for manufacturing a thermoelectric structure comprising the following steps:
a) providing a substrate made from a first material,
b) depositing a thermoelectric element made from a second material on the substrate, by additive manufacturing, preferably by selective laser sintering or by laser powder bed fusion,
c) thinning and cutting the substrate until a film made from the first material is obtained, to obtain a thermoelectric structure comprising a film and the thermoelectric element.

2. The method according to claim 1, wherein the substrate is covered, completely or locally, with a metal bonding layer made from a third material and in that the thermoelectric element is formed on the metal bonding layer, by means of which a thermoelectric structure comprising a film, a bonding layer and a thermoelectric element is obtained, the third material preferably being selected from Al, Ti, Cu, Au and Ni.

3. The method according to claim 1, wherein the thermoelectric element is a part in the form of a comb delimiting a base and a plurality of arms, substantially parallel to each other, extending substantially orthogonally from the base, the plurality of arms having a first end and a second end, the first end being connected to the base, and the second end being in contact with the film or, where applicable, in contact with the metal bonding layer.

4. The method according to claim 1, wherein the thermoelectric element is a pin, having a base and a height.

5. The method according to claim 4, wherein the substrate is cut so as to have a film having the same surface area as the surface area of the base of the pin.

6. The method according to claim 4, wherein the substrate is cut so as to have a film having a surface area greater than the surface area of the base of the pin.

7. The method according to claim 4, wherein, between step b) and step c), the method comprises an additional step during which an intermediate metallisation layer and then an additional thermoelectric element, which is made from a fourth material having a conductivity type opposite to the conductivity type of the second material, are deposited on the thermoelectric element.

8. The method according to claim 6, wherein, in step b), a plurality of pins are deposited and in that the substrate is cut so as to have a structure comprising a film on which a plurality of pins are disposed.

9. The method according to claim 1, wherein the second material is selected from Si, SiGe, Bi₂Te₃, Half-Heusler and Skutterudites.

10. The method according to claim 1, wherein the first material is 316L steel, aluminium, titanium, a CuZr alloy, a ceramic or graphite.

11. The thermoelectric structure obtained by the method according to claim 1, comprising a film, for example made from 316L steel, aluminium, titanium, CuZr alloy, ceramic or graphite, on which one or more thermoelectric elements are disposed.

12. The thermoelectric structure according claim 1, wherein a metal bonding layer, for example made from Al, Ti, Cu, Au or Ni, is disposed between the film and the thermoelectric element or elements.

13. The thermoelectric device comprising two thermoelectric structures according to claim 11, each structure comprising a film, for example made from 316L steel, aluminium, titanium, CuZr alloy, ceramic or graphite, and one or more thermoelectric elements,
a metal bonding layer, for example made from Al, Ti, Cu, Au or Ni, being able to be disposed between the film and the thermoelectric element or elements of the two thermoelectric structures,
the thermoelectric element or elements of one of the thermoelectric structures being of a first conductivity type and the thermoelectric element or elements of the other thermoelectric structure being of a second conductivity type opposite to the first conductivity type.
